(19) United States
(12) Patent Application Publication
(10) Pub. No.: US 2010/0066388 A1
(43) Pub. Date: Mar. 18, 2010

(54) EPITAXIAL SOOT SENSOR

(75) Inventors: Karlheinz WIENAND, Aschaffenburg (DE); Karl-Heinz ULLRICH, Gross-Umstadt (DE)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: HERAEUS SENSOR TECHNOLOGY GMBH, Hanau (DE)

(21) Appl. No.: 12/558,829

(22) Filed: Sep. 14, 2009

(30) Foreign Application Priority Data
Sep. 15, 2008 (DE) 10 2008 047 369.3

(51) Int. Cl. G01R 27/28; G03F 7/20; C30B 29/02; B32B 37/00

(52) U.S. Cl. 324/649; 430/319; 117/11; 156/60

(57) ABSTRACT

A soot sensor has a soot-sensitive noble-metal structure formed as strip conductor sections on an electrically insulating carrier, whose strip conductor sections are between 5 and 100 μm wide and are spaced apart from each other between 5 and 100 μm. The electrically insulating carrier may be a single crystal and the noble metal crystallized out on a surface of the single crystal, or the electrically insulating carrier may be polycrystalline and the noble metal crystallized out on the polycrystalline, electrically insulating carrier.

### BACKGROUND OF THE INVENTION

The present invention relates to soot sensors based on platinum thin-film structures sensitive to carbon particulates (soot).

Thick-film structures manufactured in mass production have strip (track) conductor structures too coarse for precise measurements. The finer thin-film structures detach from the substrate during use.

International patent application publication WO 2006/111386 discloses soot sensors with IDK and heat-conductor structures on electrically insulating substrates. The decisive feature is that the soot interacts with the soot-sensitive structure, whereby the soot-sensitive structure is not covered. For continuous use of such open structures, the structures open to the soot are annealed with a heat conductor arranged, for example, on the reverse side of a substrate, and thereby freed from soot. However, it is problematic that the platinum structures detach under operating conditions. Therefore, such soot sensors have a short service life.

### BRIEF SUMMARY OF THE INVENTION

The object of the present invention consists in providing highly sensitive structures, sensitive to soot, that can be manufactured in mass production with long service lives.

To achieve this object, the noble metal, preferably platinum, is fixed rigidly on the insulating substrate. For this purpose, according to the invention, a crystalline, preferably epitaxial, growth of the noble metal, preferably platinum, takes place on an electrically insulating carrier, preferably a single crystal.

Crystalline, preferably oriented (epitaxial) growth of the noble metal on the carrier causes a more rigid bonding of the noble-metal layer, preferably platinum layer, relative to a typically amorphous thin-film structure. With increasing crystallinity of the boundary surfaces, the soot sensor can be loaded with respect to its operating conditions. Crystalline, preferably epitaxially deposited, noble-metal layers are structured with typical methods, e.g. photolithography, into fine structures that are thus especially sensitive to soot, preferably comb structures (IDK structures). Here, strip conductor sections are created with widths and spacings from each other between 5 and 100 μm, preferably 10 to 50 μm. Epitaxial layer thicknesses of 0.2 to 2 μm, preferably 0.5 to 2 μm, more preferably 0.8 to 1.5 μm, have proven themselves. Below 0.2 μm, impurities cause a relatively high drift. The manufacturing expense and use of materials is no longer justifiable for layer thicknesses greater than 5 μm.

Preferred single crystals are sapphire (alpha-Al₂O₃), MgO, and spinel. For crystallinity of PCA (polycrystalline alumina) in the narrower sense, a crystalline composite can be achieved, which distinguishes itself, with respect to adhesion of the noble metal on its polycrystalline carrier, by improved adhesion relative to typical coatings.

According to the invention, the chip with the soot-sensitive structure manufactured with a complicated process, preferably for mass production, is fixed very advantageously on a simple substrate having a heat conductor. While the soot-sensitive structure, secured against detachment by increased expense, can be used in an exposed configuration, the simple heat conductor structure arranged on a substrate is covered and thereby prevented from detachment. Mass production is very effective for soot sensors, in which strip conductors on simple substrates are covered and chips are fixed, preferably adhered, on top with more rigidly adhering structures sensitive to soot under the operating conditions.

In a preferred embodiment, the single crystal with the oriented, grown platinum soot-sensitive structure is mounted on a substrate with heat conductors, so that the single crystal covers the heat conductors, whereby, in contrast to the platinum soot-sensitive structure, the heat conductor is protected. Especially for mass production, in a cost and material saving way, a simple heat conductor is arranged on a simple substrate and the carrier bearing the soot-sensitive structure, which, in comparison, is more complicated, preferably a single crystal with the crystalline, preferably epitaxial, structure is mounted on the heat conductor.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is an exploded, perspective view showing a construction of a soot sensor according to one embodiment of the present invention;

FIG. 1a is side, sectional view showing the arrangement of the layers, still slightly exploded, of the soot sensor according FIG. 1;

FIG. 2 is a further exploded, perspective view of a construction of a soot sensor according to an embodiment of the present invention; and

FIG. 3 is a plan view of a test arrangement for analyzing adhesion.

### DETAILED DESCRIPTION OF THE INVENTION

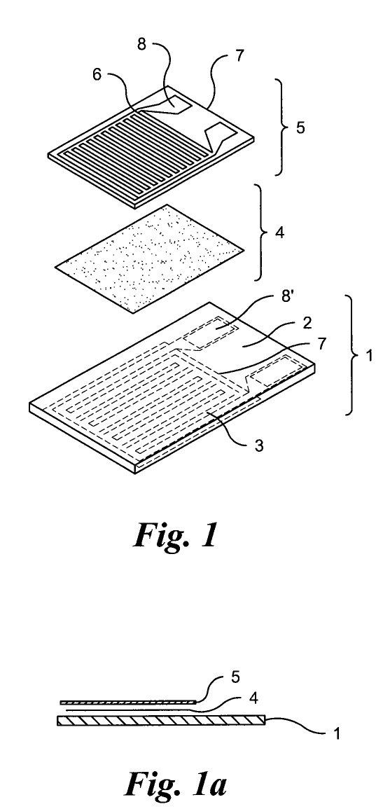

FIG. 1 shows a heating chip 1 composed of a substrate 2 with a heat conductor 3 having contact fields 8′, an adhesive layer 4, and a measurement resistor (chip 5) in which the soot-sensitive structure 6 having contact fields 8 is crystallized out on the crystal structure of the carrier 7.

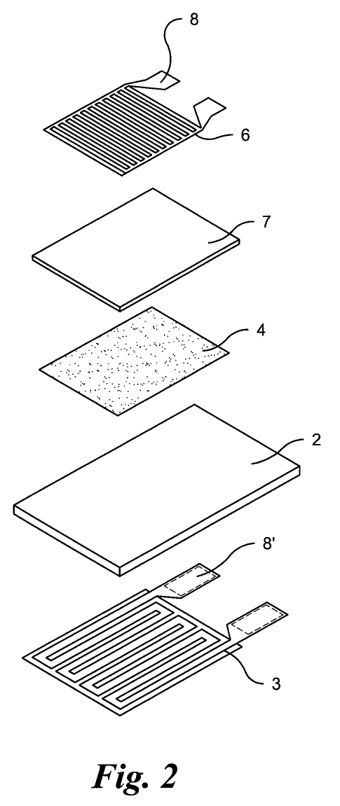

FIG. 2 shows a general exploded view composed of the heat conductor 3 with contact fields 8′, substrate 2, adhesive layer 4, crystalline carrier 7, and a crystallized, soot-sensitive structure 6 with contact fields 8 on the crystals of the crystalline carrier. The heat conductor 3, preferably made of platinum or platinum alloy, is deposited on the electrically insulating substrate 2, preferably made of aluminum oxide, in conventional thin-film or thick-film technology. The heat-conductor, thin-film structure 3 is protected from environmental effects by a glaze. Thus, the heat-conductor, thin-film structure 3 has a durable, sealed construction for operation as a soot sensor. Furthermore, a carrier 7 is mounted on this substrate 2, and on this carrier 7 a soot-sensitive structure 6 is attached. In one embodiment, the carrier 7 covers the heat conductor 3. Advantageously, however, the carrier 7 is adhered on the side of the substrate 2 facing away from the heat conductor 3. This has the advantage that the electrical connections can be better separated from each other. The mounting of the carrier 7 is realized advantageously with a layer 4 made of glass solder or cement.

This general configuration also includes the preferred configuration according to FIG. 1, according to which the two outer structures are prefabricated as chips 1, 5 and bonded together with the middle adhesive layer 4. Considering that it is significantly more complicated to crystallize out, preferably to crystallize epitaxially, a noble-metal layer, preferably a platinum layer, on an electrically insulating crystal structure, preferably on sapphire (alpha-Al₂O₃), two mass production lines are operated separately from each other in which, in one production line, the chips 5 that are complicated to manufacture with the soot-sensitive structure 6 are produced and, in a different line, the easy-to-manufacture substrates 2 with the heat-conductor structure 3 are produced. After dividing the chips 1, 5 produced in large batches into individual pieces, the different chips 1, 5 are bonded together in a simple processing step. The efficiency of this procedure lies in that the expensive production costs are limited to the production of the complicated chips 5. The soot-substrate. Thus, in serial production the soot-sensitive structure 6 is more difficult to detach from its carrier 7 than the heat-conductor structure 3 is to detach from its substrate 2.

The expense for mounting the soot-sensitive layer 6 is justified by the increased service life relative to previous thin films and increased sensitivity relative to thick films. In contrast, the heat conductor 3 does not need to be exposed to the medium. The heat conductor is protected in a simple way for achieving its function. For this purpose, a construction in thick-film technology or a glaze on a construction in thin-film technology is sufficient, for example the adhesive 4 arranged between the chips 1, 5 and provided for its mounting. Alternatively, the heat conductor 3 could also be protected with a thin-film coating made of an electrically insulating material, for example aluminum oxide (not shown in the Figures) facing away from the measurement chip 5 to be bonded on the other side of the substrate 2.

The decisive feature for the longevity of the soot-sensitive structure 6 according to the invention is the construction of the crystal structure of the noble-metal layer 6 on the crystal 7 or the crystals of the electrically insulating carrier 7 along with the avoidance of amorphous transition regions from the carrier 7 to the noble metal 6. Here, an advantage according to the invention can already be realized relative to conventional ceramic substrates, particularly made of aluminum oxide, if instead a coarser crystalline structure is used, which is connected to the finish PCA. Thus, preferably, the soot sensor has a coarser crystalline transition structure from the electrically insulating carrier 7 to the noble-metal structure 6 than the transition structure from the substrate 2 to the heat conductor structure 3. Ideally, the crystallization of the noble-metal layer 6 is performed on single crystals 7, for example sapphire or MgO. An optimum result is achieved by oriented (epitaxial) growth on a single crystal 7.

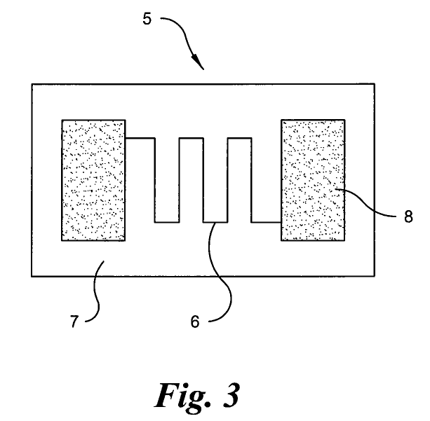

Adhesion tests were performed on platinum measurement resistors Pt10000 according to FIG. 3. Comparison tests of chips of FIG. 3, corresponding to platinum structures on thin-film aluminum oxide ceramic, were set for 30 minutes in a water/glycerin mixture composed of one volume part deionized water and four volume parts glycerin at room temperature and then rinsed in water. Here, all platinum structures were undercut and detached.

### Example 1

Five measurement resistors 5, in which platinum measurement resistors Pt10000 according to FIG. 3 are structured photolithographically in a platinum layer deposited epitaxially on sapphire substrate 7 to form the structure 6, 8 according to FIG. 3, are treated analogously to the comparison test for 30 minutes in a water/glycerin mixture made of deionized water and glycerin in the volume ratio of 1:4 at room temperature and then rinsed with water. In contrast to the comparison test, all of the strip conductors were still bonded rigidly onto the substrate.

### Example 2

Two wires are fused to the two contact fields 8 on a measurement resistor 5 according to Example 1. After that, the measurement resistor was dipped at room temperature into a 10% sulfuric acid solution. Then, a current of 1 mA was sent through the measurement resistor for 10 hours. After the end of the test, all of the platinum structures 6, 8 still adhered to their substrate 7.

### Example 3

A platinum wire was fused to a contact field 8 on a measurement resistor 5 according to Example 1. After that, the measurement resistor 5 was immersed at room temperature into a 10% sulfuric acid solution. The wire was connected to the negative pole of a current source, whose positive pole, made of an electrode, was immersed into the solution. A current of 1 mA was sent through the electrolyte for a period of 10 hours. After the end of the test, the platinum structures still adhered rigidly to the structure.

In comparison tests, Pt structures produced in standard-type thin-film technology detached from a standard substrate after only a few minutes.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A soot sensor comprising a soot-sensitive noble-metal structure formed as strip conductor sections on an electrically insulating carrier, whose strip conductor sections are between 5 and 100 μm wide and are spaced between 5 and 100 μm apart from each other, wherein the electrically insulated carrier is a single crystal and the noble metal is crystallized out on a surface of the single crystal, or the electrically insulating carrier is polycrystalline and the noble metal is crystallized out on the polycrystalline, electrically insulating carrier.

2. The soot sensor according to claim 1, wherein the noble metal is arranged epitaxially on the carrier.

3. The soot sensor according to claim 1, wherein the soot-sensitive structure has a layer thickness of 0.2 to 2 μm.

4. A soot sensor comprising a soot-sensitive noble-metal structure (6) on an electrically insulating carrier (7) and a heat-conductor structure (3) on an electrically insulating substrate (2) different from the carrier (7), wherein the carrier (7) with the noble-metal structure (6) has a coarser crystalline transition structure from the electrically insulating carrier (7) to the noble-metal structure (6) than a transition structure from the substrate (2) to the heat conductor structure (3).

5. A method for production of a soot sensor, comprising growing a platinum layer epitaxially on an electrically insulating carrier, and structuring the epitaxial platinum layer into a soot-sensitive structure.

6. The Method according to claim 5, wherein the structuring of the platinum layer is performed photolithographically.

7. A method for production of soot sensors, comprising mutually fixing first and second different chips to each other, wherein the first chip has a heat-conductor structure and the second chip has a soot-sensitive structure, and wherein in serial production the soot-sensitive structure of the second chip is more difficult to detach than the heat-conductor structure of the first chip.
